(19) United States
(12) Patent Application Publication
(10) Pub. No.: US 2015/0308013 A1
(43) Pub. Date: Oct. 29, 2015

(54) METHOD OF PRODUCING FREE-STANDING NET-SHAPE SAPPHIRE

(71) Applicant: Rubicon Technology, Inc., Bensenville, IL (US)

(72) Inventors: John P. CIRALDO, Elgin, IL (US); Jonathan B. LEVINE, Chicago, IL (US)

(73) Assignee: RUBICON TECHNOLOGY, INC., Bensenville, IL (US)

(21) Appl. No.: 14/532,387

(22) Filed: Nov. 4, 2014

Related U.S. Application Data
(60) Provisional application No. 61/985,790, filed on Apr. 29, 2014.

(51) Int. Cl. C30B 23/02; C30B 23/08; C30B 25/06; C30B 25/18; C30B 29/20; C30B 29/68

(52) U.S. Cl. CPC C30B 23/025; C30B 29/20; C30B 29/68; C30B 25/06; C30B 25/183; C30B 23/08

(57) ABSTRACT

A method for producing one or more free-standing aluminum oxide windows or laminates by using a substrate of aluminum oxide and one or more sacrificial layers that each separates one or more deposited aluminum oxide layer. The sacrificial layer may be decomposed to producing one or more a free-standing aluminum oxide windows. The free-standing windows or laminates are substantially in finished form requiring little or no post growth processing. The produced windows or laminates may be hard, scratch resistant net-shaped sapphire ready for use in cell phones, electronic devices, a tablet computer, watches, glass applications, or the like.

This application claims priority and benefit of U.S. Provisional Application No. 61/985,790 filed Apr. 29, 2014, the disclosure of which is incorporated by reference herein in its entirety.

### BACKGROUND OF THE DISCLOSURE

1.0 Field of the Disclosure

The present disclosure relates to a method for inter alia producing net-shaped aluminum oxide and, more particularly, a method for producing free-standing net-shaped aluminum oxide, such as sapphire, e.g., by a epitaxy-based process.

2.0 Related Art

Hard, scratch-resistant windows such as aluminum oxide are often necessary for a wide variety of applications such as electronic devices where glass does not perform well. For example, sapphire's high optical transmission across the visible spectrum, as well as its high resistance to breaking and scratching, makes it an appealing material to replace soft materials such as, e.g., plastic and various types of glass.

However, the current processes for producing sapphire are too laborious and expensive to allow a wide adoption of sapphire/aluminum oxide windows. Moreover the current techniques are generally limited to producing windows that are flat shaped, usually by cutting and polishing the window from a larger crystal.

Therefore, a technique to provide an aluminum oxide type window of similar hardness and scratch resistance that does not require expensive and time-intensive efforts to cut and polish the window from a large crystal would likely be of great use. Further, if the aluminum oxide type window is producible in arbitrary shapes and thicknesses that does not require extensive processing post-growth, substantial improvements in overall aluminum oxide window production and usage might be realized.

### SUMMARY OF THE DISCLOSURE

According to one non-limiting aspect of the disclosure, a method is provided for producing one or more free-standing aluminum oxide windows or laminates by using a substrate of aluminum oxide and one or more sacrificial layers that each separates one or more deposited aluminum oxide layers. The sacrificial layers may be decomposed producing one or more free-standing aluminum oxide windows. The free-standing windows or laminates are substantially in finished form requiring little or no post growth processing. The produced windows or laminates may be hard, scratch-resistant net-shaped sapphire ready for use in cell phones, electronic devices, watches, glass applications or the like.

According to one non-limiting example of the disclosure, a method is provided to create one or more aluminum oxide sheets or windows by creating a super-lattice structure having one or more sacrificial layers to isolate the one or more layers of aluminum oxide from one another during the process. A substrate such as, e.g., a sapphire substrate is used as a basis for creating the one or more aluminum oxide sheets or windows, epitaxially. A sacrificial layer is created on the substrate, followed by the deposition of a first aluminum oxide layer on the sacrificial layer. The process may be continued to create yet another sacrificial layer on the first aluminum oxide layer followed by another layer of aluminum oxide layer on the sacrificial layer. Multiple layers may be created in this fashion, alternating a sacrificial layer and an aluminum oxide layer to produce a super-lattice. Once a super-lattice is formed, the sacrificial layers may be decomposed resulting in free-standing windows or laminates. A plurality of the sacrificial layers may be decomposed simultaneously.

In one aspect of the disclosure, a process is provided for producing net-shaped aluminum oxide windows comprising the steps of providing an aluminum oxide substrate, layering a sacrificial layer on the substrate, creating an aluminum oxide layer on the sacrificial layer, and decomposing the sacrificial layer to create a free-standing aluminum oxide window or laminate. The process may further include layering at least one additional sacrificial layer and creating at least one additional aluminum oxide layer, so that the at least one additional sacrificial layer separates two adjacent aluminum oxide layers. Any two of the sacrificial layers may comprise a different compound. The at least one additional sacrificial layer may comprise a plurality of additional sacrificial layers, further comprising the step of decomposing all the additional sacrificial layers simultaneously. The step of decomposing all the additional sacrificial layers may decompose all the additional sacrificial layers by chemical decomposition or heat decomposition. The step of decomposing may decompose all sacrificial layers simultaneously to produce the free-standing aluminum oxide window or laminate. A subset of the sacrificial layers may be decomposed simultaneously.

In one aspect, a process for producing net-shaped aluminum oxide windows includes the steps of: layering at least one sacrificial layer on a substrate, creating at least one aluminum oxide layer on the at least one sacrificial layer sacrificial layer, and decomposing the at least one sacrificial layer to create a free-standing aluminum oxide window or laminate, wherein the at least one sacrificial layer has a geometrically compatible atomic structure with the at least one aluminum oxide layer and the substrate to promote pseudomorphic growth of any subsequent layers. The at least one sacrificial layer may comprise a plurality of sacrificial layers and the at least one aluminum oxide layer may comprise a plurality of aluminum oxide layers wherein the plurality of sacrificial layers and the plurality of aluminum oxide layers alternate. Any two of the plurality of sacrificial layers may comprise a different compound. The thickness of the at least one aluminum oxide layer may be about 5 microns to about 500 microns and the thickness of the at least one sacrificial layer may be about 10 nanometers to about 200 nanometers. The process may further comprise the step of using the free-standing aluminum oxide window or laminate in a cell phone, an electronic device, a watch or a glass application.

Additional features, advantages, and embodiments of the disclosure may be set forth or apparent from consideration of the detailed description, drawings and attachment. Moreover, it is to be understood that the foregoing summary of the disclosure and the following detailed description, and drawings are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate embodiments of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 is an example illustration of a super-lattice 100 of alternating layers of Al₂O₃ 105a-105c formed during an epitaxial-based process on an aluminum oxide substrate 102 such as, e.g., sapphire, configured according to principles of the disclosure.

FIG. 2 shows an example of a super-lattice created by a process of the disclosure, and being decomposed to produce a net-shaped window of laminate, the steps of the process performed according to principles of disclosure;

FIG. 3 is an illustration similar to FIG. 2 except that the substrate. The formed sacrificial layers, and the aluminum oxide layers are shown curved; and

FIG. 4 is a flow diagram of a process for producing one or more aluminum oxide windows or laminates, the steps of the process performed according to principles of the disclosure.

### DETAILED DESCRIPTION OF THE DISCLOSURE

The disclosure and the various features and advantageous details thereof are explained more fully with reference to the non-limiting examples that are described and/or illustrated in the accompanying drawings and detailed in the following description. It should be noted that the features illustrated in the drawing are not necessarily drawn to scale, and features of one example may be employed with other examples as the skilled artisan would recognize, even if not explicitly stated herein. Descriptions of well-known components and processing techniques may be omitted so as to not unnecessarily obscure the principles of the disclosure. The examples used herein are intended merely to facilitate an understanding of ways in which the disclosure may be practiced and to further enable those of skill in the art to practice the examples of the disclosure. Accordingly, the examples herein should not be construed as limiting the scope of the disclosure. Moreover, it is noted that like reference numerals represent similar parts throughout the several views of the drawings.

The terms “including”, “comprising” and variations thereof, as used in this disclosure, mean “including, but not limited to”, unless expressly specified otherwise. The term “about” herein means within 10% of the specified amount or number unless context states otherwise.

The terms “a”, “an”, and “the”, as used in this disclosure, means “one or more”, unless expressly specified otherwise.

Devices that are in communication with each other need not be in continuous communication with each other, unless expressly specified otherwise.

Although process steps, method steps, algorithms, or the like, may be described in a sequential order, such processes, methods and algorithms may be configured to work in alternate orders. In other words, any sequence or order of steps that may be described does not necessarily indicate a requirement that the steps be performed in that order. The steps of the processes, methods or algorithms described herein may be performed in any order practical. Further, some steps may be performed simultaneously.

When a single device or article is described herein, it will be readily apparent that more than one device or article may be used in place of a single device or article. Similarly, where more than one device or article is described herein, it will be readily apparent that a single device or article may be used in place of the more than one device or article. The functionality or the features of a device may be alternatively embodied by one or more other devices which are not explicitly described as having such functionality or features.

The disclosure is generally directed to a process for producing one or more free-standing sheets of aluminum oxide such as, e.g. sapphire windows, employing an epitaxy-based technique. The resultant sheets or windows may be net-shaped or near net-shaped, requiring very minimal or no final processing.

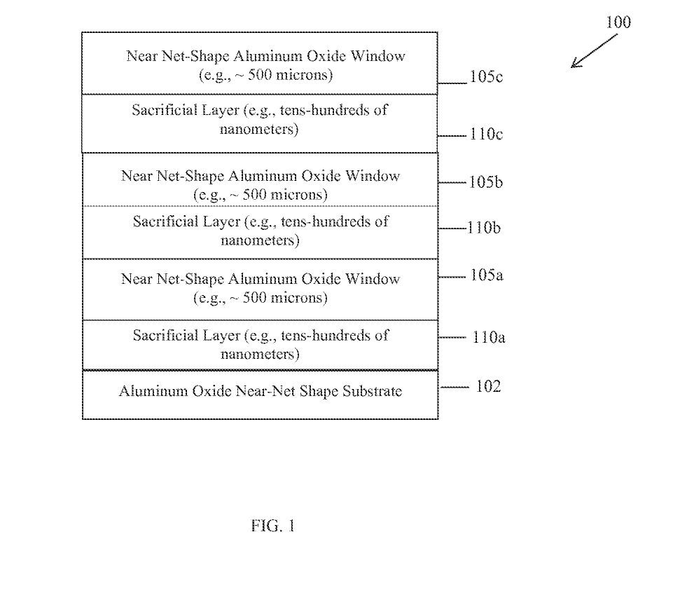

FIG. 1 is an example illustration of a super-lattice 100 of alternating layers of Al₂O₃ 105a-105c formed during an epitaxial-based process on an aluminum oxide substrate 102 such as, e.g., sapphire, configured according to principles of the disclosure. The composition of the aluminum oxide layers 105a-105c may be Al₂O₃, or it may be rich or deficient in either element corresponding to Al_{2+/-x}O_{3+/-y}. The substrate 102, which may be a sapphire crystal, is coated with a first sacrificial layer 110a which may be a metal-oxide such as, e.g., nickel oxide, zinc oxide or chromium oxide, but not aluminum oxide. The material for the sacrificial layer(s) is chosen based on its ability to be atomically compatible (e.g., lattice parameters) with the crystal formation to be layered upon it. In some applications, the sacrificial layers may also comprise material that is not a metal oxide. Moreover, the sacrificial layer may comprise a pure or substantially pure metal, or a compound not containing oxygen.

Once the first sacrificial layer 110a is completed, a first Al₂O₃ layer 105a, which may be sapphire, is deposited onto the first sacrificial layer 110a. The desired thickness of the Al₂O₃ layer 105a (or any other Al₂O₃ layer) may be selected from the range from 25 microns to about 150 microns, or may be selected from a range from about 10 microns to about 23 microns, or may be selected from a range from greater than 100 microns to about 500 microns. However, the process is suitable to create thicknesses of less than 10 microns or greater than 500 microns of the Al₂O₃ layer. It is even possible to create one or more Al₂O₃ layers of less than 1 micron. The process may be stopped at this point, or the process may continue to produce a single crystal super-lattice 100 based on the substrate 102.

Producing a super-lattice of several Al₂O₃ layers may be more efficient to produce over just producing a single Al₂O₃ layer since the production of several Al₂O₃ layers can be achieved without having to re-establish a production environment anew such as, e.g., re-initiating a vacuum repeatedly. In the case of producing multiple Al₂O₃ layers, a vacuum may have to be established only once, saving production time and improving production efficiency.

The process may continue with formation of additional layers of sacrificial layers 110b, 110c alternating with additional layers 105b, 105c of Al₂O₃. The desired thickness of the additional layers 105b, 105c of Al₂O₃ may be selected from ranges like layer 105a, described above. Each layer 105b, 105c may be the same thickness, or may be a different thickness from one another. The sacrificial layers 110a-110c may have a thickness that might be selected from a range of about 10 nanometers to about 200 nanometers, although the range may vary beyond this range.

The sacrificial layers may be produced by a deposition technique which might include a sputtering technique or a vapor deposition technique. Examples of depositing a metal oxide are described in U.S. patent applications Ser. Nos. 14/101,957 and 14/101,980.

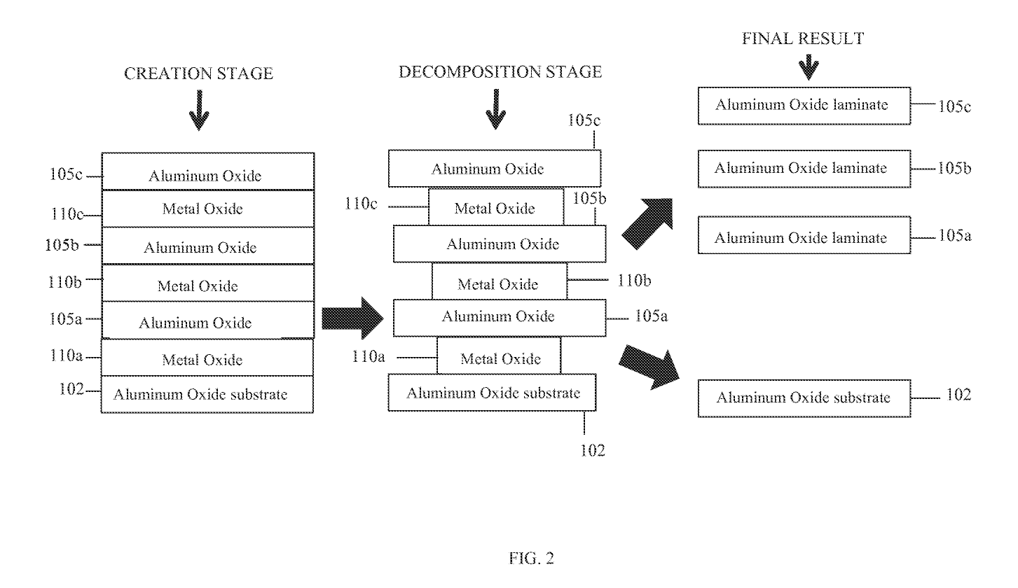

The sacrificial layers 110a-110c may isolate the epitaxially grown sheets or windows, i.e., layers 105a-105c, and provide a basic structural support during the creation of the layers 105a-105c. Once the number of desired layers 105a-105c have been created, such as shown in the example of FIG. 2, the sacrificial layers 110a-110c may be decomposed, resulting in free-standing aluminum oxide sheets or windows 105a-105c. These resulting sheets or windows 105a-105c may be net-shaped requiring little or no post processing to finish the windows or laminates. Moreover, the resulting window(s) 105a-105c may be essentially ready for use in an end application, such as a target device. The substrate 102 may be reused.

The decomposition of the sacrificial layers 110a-110c may be accomplished through chemical techniques such as the use of acids to dissolve the sacrificial layers 110a-110c, while not affecting the sheets or windows 105a-105c. Alternatively, the sacrificial layers 110a-110c may be decomposed using a thermal decomposition technique. Decomposition of all the sacrificial layers in the super-lattice may occur in a single decomposition process instead of an iterative decomposition process for each layer. Preferably, the sacrificial layers 110a-110c may be decomposed simultaneously, creating multiple finished windows or laminates. Although, it is possible to decompose a single sacrificial layer, perhaps repetitively.

The sacrificial layers 110a-110c may comprise different compounds (e.g., different metal oxides) so that a particular sacrificial layer, e.g., layer 110a, comprises a first type of sacrificial compound and another sacrificial layer(s), e.g., layer 110b, 110c, may comprise a different type of sacrificial compound. By selectively choosing different compounds for the sacrificial layers, selective decomposition may be achieved so that a particular sacrificial layer(s) can be decomposed, while another sacrificial layer(s) does not decompose. For example, a first type of sacrificial layer compound might be decomposed by a particular temperature while the other sacrificial layers comprising a different compound would not decompose at the particular temperature. Alternatively, e.g., a first sacrificial layer(s) comprising a first type of compound might be decomposed by a particular chemical (e.g., a first type of acid) while the other sacrificial layer(s) comprising a different compound would not be decomposed by the particular chemical. In this way, a stack of windows or laminates (or, a subset of the windows or laminates) might be maintained together structurally (e.g., for production, processing, handling, shipping and/or stocking considerations) after the selected sacrificial layer (i.e., the first sacrificial layer comprising a first type of compound) is decomposed. The remaining windows or laminates (or the subset) may be separated later using a different temperature or a different chemical, as appropriate, to decompose the remaining sacrificial layer(s) comprising a different type of compound as compared with the first type of compound. The subset may be separated into individual layers simultaneously.

The sacrificial layers 110a-110c may be selected to provide a geometrically compatible atomic structure with the intended Al₂O₃ layers 105a-105c and the substrate 102. The lattice parameters of the atomic spacing of the layers and substrate are typically within about 9% of one another, or lower, to ensure or promote pseudomorphic growth of the subsequent layers. In some instances, the material used for the sacrificial layer(s) may be chosen such that any integer multiple of the atomic spacing is within about 9% of the aluminum oxide's atomic spacing.

In order to ensure process compatibility with the growth of aluminum oxide laminates or windows, the sacrificial layers used in the super-lattice need to satisfy several physical requirements beyond lattice compatibility. In order to address potential reactivity with the aluminum oxide; the use of metal oxides such as nickel oxide may be preferable. Furthermore, as certain steps in the process may require substrate heating, the material used must be stable across the full temperature ranges used in the fabrication of the super-lattice. Depending on the method used for decomposition of the sacrificial layer(s), the material used may also need to satisfy specific chemical requirements. For example, if the sacrificial layer is to be decomposed chemically, the additional requirement exists that the material must be subject to decomposition via a chemical process that does not denigrate the properties of the aluminum oxide layers. To satisfy the requirements of chemical decomposition, oxidized transition metals may be used. In one example, nickel oxide, having satisfactory lattice compatibility and thermal stability, is used as a sacrificial layer. Upon fabrication of the super-lattice structure, the nickel oxide may be decomposed in a reactive etchant at sufficiently low temperatures such that the sapphire films remain intact and undamaged. In another example, zinc-oxide may be selected as the sacrificial layer for thermal decomposition. The use of thermally decomposable material such as, e.g., zinc oxide, may be utilized in a process where the super-lattice is grown below the decomposition temperature of the thermally decomposable material. For zinc-oxide, this decomposable temperature is about 1975° Celsius at 1 atm of pressure. The final super-lattice structure may then be heated to a specific set point above the decomposition temperature of the zinc-oxide, but below the melting temperature of the aluminum oxide for such time that the sacrificial layers are fully decomposed, leaving only the sapphire laminates.

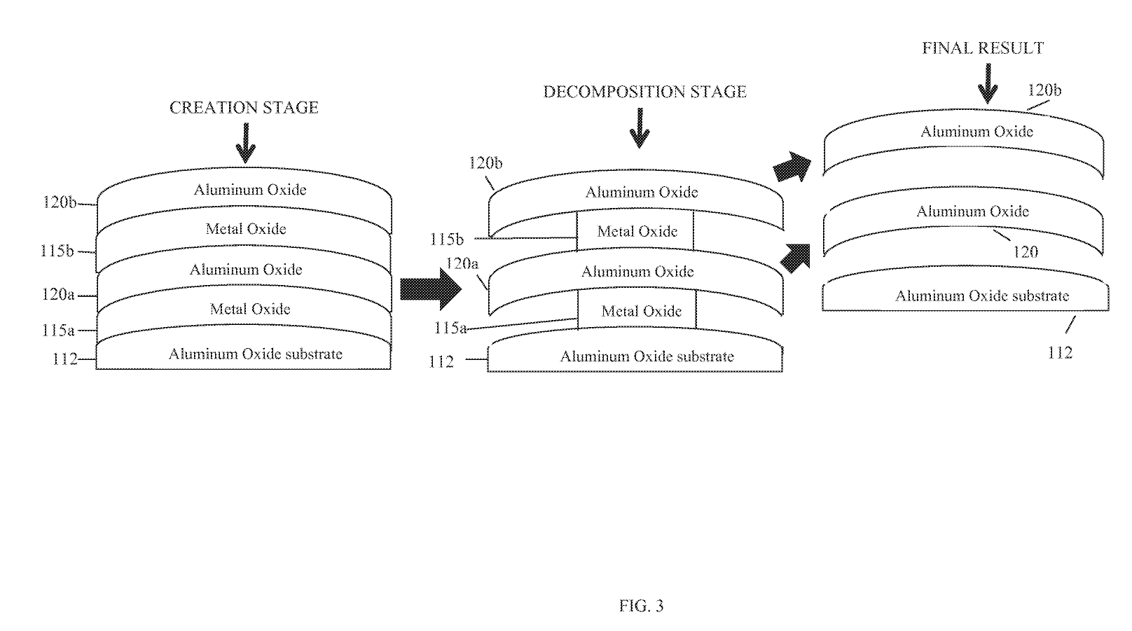

FIG. 3 is an illustration similar to FIG. 2 except that the substrate 112 and formed sacrificial layers of metal oxide 115a, 115b, and the aluminum oxide layers 120a, 120b are shown configured as a curved structure. The desired thickness of the Al₂O₃ layer(s) 120a, 120b may be selected from the range from 25 to about 150 microns, or may be selected from a range from about 10 to about 20 micron, or may be selected from a range from about 200 to about 500 microns. The desired thickness of the Al₂O₃ layer(s) 120a, 120b may be selected from the range from about 5 microns to about 500 microns. However, the process is suitable to create a Al₂O₃ layer thicknesses of less than 5 microns or greater than 500 microns of the Al₂O₃ layer(s). The substrate 112 may be reused for another cycle of production.

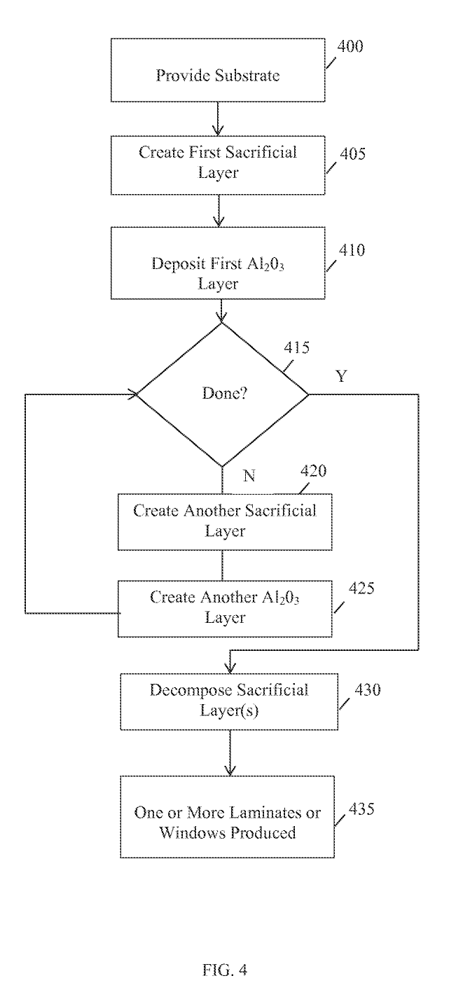

FIG. 4 is a flow diagram of a process for producing one or more aluminum oxide windows or laminates, the steps performed according to principles of the disclosure. At step 400, a substrate of aluminum oxide (e.g., substrate 102, 112) may be provided that may have a net shape and size for use in a target application. At step 405, a first sacrificial layer (e.g., 110a, 115a) may be created on the substrate. At step 410, a first aluminum oxide layer (e.g., 110a, 120a) may be deposited or expitaxially formed on the first sacrificial layer. At step 415, a decision may be made to determine if the number of layers is deemed sufficient, perhaps according to a predetermined plan. If not, another sacrificial layer may be created on the previously created aluminum oxide layer. At step 525, another aluminum oxide layer may be deposited or expitaxially formed on the prior sacrificial layer. The process may continue at step 415.

If at step 415, the number of layers is deemed sufficient, then at step 430, the sacrificial layer(s) may be decomposed. A plurality of sacrificial layers, if there are more than one, may be decomposed at the same time. This may be accomplished, e.g., by chemical or heat decomposition. Alternatively, a single sacrificial layer may be decomposed. At step 435, once the decomposition is completed, one or more free-standing laminates or full windows may be produced.

The steps or processes described herein permit the creation of either a laminate or a full window that is flat, or has a radius such as one or more curves. Moreover, the process described herein permits creation of a window or sheet that has angles, such as, e.g., right angles or near right angles. The windows or sheets may be produced conformal to nearly any 3-D shape. The width and length of the created windows may have a wide range of sizes, but could easily have a length or width of up to six inches or more.

The resulting window(s) 105a-105c may have characteristics that include high optical transmission across the visible spectrum, as well as its high resistance to breaking and scratching. The resulting window(s) 105a-105c may be used in a wide variety of applications including cell phones, computers, watches, electronic devices, glass-containing devices, or the like.

The process described herein is highly scalable and utilizes many techniques demonstrated in large scale production. Moreover, the process described herein eliminates costly post-growth processing that is common in traditional sapphire type production, such as lapping, polishing and cutting to final shape for intended target use. The processes herein may be used to produce either one or more laminates or one or more full windows. The achievable thickness may be much smaller (thinner) than conventionally produced windows or laminates.

While the disclosure has been described in terms of examples, those skilled in the art will recognize that the disclosure can be practiced with modifications in the spirit and scope of the appended claims. These examples are merely illustrative and are not meant to be an exhaustive list of all possible designs, embodiments, applications or modifications of the disclosure. Any patent document mentioned herein is incorporated herein by reference.

What is claimed:

1. A super-lattice comprising:
a substrate of aluminum oxide;
a first sacrificial layer of metal oxide on the substrate; and
a first layer of aluminum oxide deposited on the first sacrificial layer.

2. The super-lattice of claim 1, wherein the aluminum oxide is sapphire.

3. The super-lattice of claim 1, further comprising one or more additional sacrificial layers and one more additional aluminum oxide layers, in alternating sequence.

4. The super-lattice of claim 3, wherein any of the sacrificial layers has a thickness of about 10 nanometers to about 200 nanometers and the thickness of any of the aluminum oxide layers is about 5 microns to about 500 microns.

5. The super-lattice of claim 1, wherein the metal oxide is nickel-oxide, zinc oxide or chromium oxide.

6. A process for producing net-shaped aluminum oxide windows comprising the steps of:
providing an aluminum oxide substrate;
layering a sacrificial layer on the substrate;
creating an aluminum oxide layer on the sacrificial layer; and
decomposing the sacrificial layer to create a free-standing aluminum oxide window or laminate.

7. The process of claim 6, further comprising the steps of:
layering at least one additional sacrificial layer and creating at least one additional aluminum oxide layer, so that the at least one additional sacrificial layer separates two adjacent aluminum oxide layers.

8. The process of claim 7, wherein any two of the sacrificial layers comprise a different compound.

9. The process of claim 7, wherein the at least one additional sacrificial layer comprises a plurality of additional sacrificial layers, further comprising decomposing all the additional sacrificial layer simultaneously.

10. The process of claim 9, wherein the step of decomposing all the additional sacrificial layers decomposes all the additional sacrificial layers by chemical decomposition or heat decomposition.

11. The process of claim 7, wherein the step of decomposing decomposes all sacrificial layers simultaneously to produce the free-standing aluminum oxide window or laminate.

12. The process of claim 7, further comprising decomposing a subset of the sacrificial layers simultaneously.

13. The process of claim 6, wherein the decomposing step decomposes the sacrificial layer by chemical decomposition or heat decomposition to produce the free-standing aluminum oxide window or laminate.

14. A window or laminate produced by the process of claim 6.

15. The process of claim 6, wherein the layering step layers the sacrificial layer on the substrate by a deposition technique.

16. The process of claim 6, wherein the sacrificial layer has a geometrically compatible atomic structure with the aluminum oxide substrate and the aluminum oxide layer to promote pseudomorphic growth.

17. A process for producing net-shaped aluminum oxide windows comprising the steps of:
layering at least one sacrificial layer on a substrate;
creating at least one aluminum oxide layer on the at least one sacrificial layer; and
decomposing the at least one sacrificial layer to create a free-standing aluminum oxide window or laminate,
wherein the at least one sacrificial layer has a geometrically compatible atomic structure with the at least one aluminum oxide layer and the substrate to promote pseudomorphic growth of any subsequent layers.

18. The process of claim 17, wherein the at least one sacrificial layer comprises a plurality of sacrificial layers and the at least one aluminum oxide layer comprises a plurality of aluminum oxide layers wherein the plurality of sacrificial layers and the plurality of aluminum oxide layers alternate.

19. The process of claim 18, wherein any two of the plurality of sacrificial layers comprise a different compound.

20. The process of claim 17, wherein the thickness of the at least one aluminum oxide layer is about 5 microns to about 500 microns and the thickness of the at least one sacrificial layer is about 10 nanometers to about 200 nanometers.

21. The process of claim 17, further comprising the step of using the free-standing aluminum oxide window or laminate in a cell phone, an electronic device, a watch or a glass application.

22. The process of claim 17, wherein the thickness of the at least one aluminum oxide layer is about 5 microns to about 500 microns and the thickness of the at least one sacrificial layer is more than 200 nanometers.
